(19) United States
(12) Patent Application Publication
(10) Pub. No.: US 2010/0213950 A1
(43) Pub. Date: Aug. 26, 2010

(54) SYSTEM IN PACKAGE BATCH TEST METHOD AND BATCH TEST SYSTEM THEREOF

(75) Inventors: I-Ru Liu, Taipei City (TW); Chao-Pin Liu, Taipei City (TW); Ju-Jung Chang, Taipei City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: AICONN TECHNOLOGY CORPORATION, Taipei (TW)

(21) Appl. No.: 12/708,758

(22) Filed: Feb. 19, 2010

(30) Foreign Application Priority Data
Feb. 20, 2009 (TW) 098105556

(51) Int. Cl. G01R 31/02

(52) U.S. Cl. 324/537

(57) ABSTRACT

A system in package (SIP) batch test method and an SIP batch test system are applicable to an unpartitioned circuit module having a plurality of devices under test (DUTs). The circuit module is loaded in a loading module of the batch test system after probing test and molding operations. A test module of the batch test system is electrically coupled to at least two DUTs. At least two testers provide two different signal tests. A signal transmission controller controls signal transmission paths between the testers and the test module. A test controller controls the two testers and the test module to test the electrically coupled DUTs in parallel and record test results of the DUTs in configuration data. Finally, the circuit module is partitioned, so as to classify the DUTs according to the test results.

### CROSS-REFERENCE TO RELATED APPLICATION

This application claims the benefit of Taiwan Patent Application No. 098105556, filed on Feb. 20, 2009, which is hereby incorporated by reference for all purposes as if fully set forth herein.

### BACKGROUND OF THE INVENTION

1. Field of Invention

The present invention relates to a system in package (SIP) test method, and more particularly to a SIP test method, batch test system, and batch test method capable of testing a plurality of devices under test (DUTs) on a circuit module in parallel before the circuit module is partitioned.

2. Related Art

In the SIP test operation according to the prior art, after a wafer or micro-strip is manufactured and performed with probing and molding operations, the wafer or micro-strip is sawn into individual DUTs, and a final test is performed on the DUTs one by one.

As known from the above depiction, the final test is performed after the wafer is sawn. Moreover, the final test inevitably includes loading and unloading the DUTs. Therefore, the qualities of the packaged devices are not known until the final test for all the DUTs is completed. Further, after the wafer or micro-strip is sawn, the shapes and volumes of the DUTs are very small, and configured circuits thereon are quite precise, so test equipment capable of positioning high-precision elements is needed to load or unload the DUTs. Moreover, the time for loading and positioning the DUTs is inevitably increased, thereby consequently extending the time for the final test.

Therefore, it is a problem that needs to be solved urgently by the industry to accelerate the final test and shorten the total test time of the final test of all the DUTs so as to obtain the quality data of the DUTs rapidly.

### SUMMARY OF THE INVENTION

The present invention is directed to an SIP test system and an SIP test method capable of shortening a total test time of a final test and obtaining quality of each packaged device rapidly.

The present invention provides an SIP batch test method, which is applied in testing an unpartitioned circuit module. The circuit module includes a plurality of DUTs and is loaded in a batch test system. The method includes: loading the circuit module and acquiring a configuration data that records configuration positions of all the DUTs on the circuit module; testing at least two in all the DUTs in parallel according to configuration data until the test is completed; and recording a plurality of test results of the DUTs in configuration data.

The present invention provides an SIP batch test system, which is applied in testing an unpartitioned circuit module. The circuit module includes a plurality of DUTs. The batch test system includes a loading module, a test module, a first tester, a second tester, a signal transmission controller, and a test controller.

The loading module is used to load the circuit module and acquires configuration data that records configuration positions of all the DUTs on the circuit module. The test module is electrically coupled to at least two in all the DUTs and is mainly for controlling the electrically coupled DUTs to receive/send signals. The first tester and the second tester are used to perform a first signal test and a second signal test. The signal transmission controller is used to control signal transmission paths between the loading module and the first tester and the second tester. The test controller is used to control the test module, the first tester, and the second tester to individually perform the first signal test and the second signal test for the DUTs coupled to the test module in parallel. A test result of any DUTs is recorded in configuration data contained in the loading module when the first signal test and the second signal test on the DUT are completed.

In the SIP batch test method and the SIP batch test system disclosed in the present invention, the circuit module is a wafer or an unpartitioned micro-strip.

As known from the above, in the SIP batch test method and the SIP batch test system disclosed in the present invention, the final test for the circuit module is completed before the circuit module is partitioned so that it is unnecessary to load the DUTs continually in the final test, and it is good for the subsequent quality control and classification of the DUTs. Moreover, more than two DUTs are tested in parallel at the same time to exactly shorten the total test time of all the DUTs.

### BRIEF DESCRIPTION OF THE DRAWINGS

The present invention will become more fully understood from the detailed description given herein below for illustration only, and thus are not limitative of the present invention, and wherein:

FIG. 1 is a block diagram of a system according to a first embodiment of the present invention;

FIG. 2 is a flow chart of an SIP batch test method according to the first embodiment of the present invention;

FIG. 3 is a block diagram of an operation of a first type of parallel test in the present invention;

FIG. 4 is a timing diagram of the first type of parallel test in the present invention;

FIG. 5 is a block diagram of an operation of a second type of parallel test in the present invention;

FIG. 6 is a timing diagram of the second type of parallel test in the present invention;

FIG. 7 is a block diagram of an operation of a third type of parallel test in the present invention;

FIG. 8 is a timing diagram of the third type of parallel test in the present invention;

FIG. 9 is a block diagram of a system according to a second embodiment of the present invention;

FIG. 10 is a block diagram of an operation of a fourth type of parallel test in the present invention;

FIG. 11 is a timing diagram of the fourth type of parallel test in the present invention;

FIG. 12 is a block diagram of an operation of a fifth type of parallel test in the present invention; and

FIG. 13 is a timing diagram of the fifth type of parallel test in the present invention.

### DETAILED DESCRIPTION OF THE INVENTION

To make the objectives, structural features, and functions of the present invention more comprehensible, the present invention is illustrated below in detail with reference to the embodiments and the accompanying drawings.

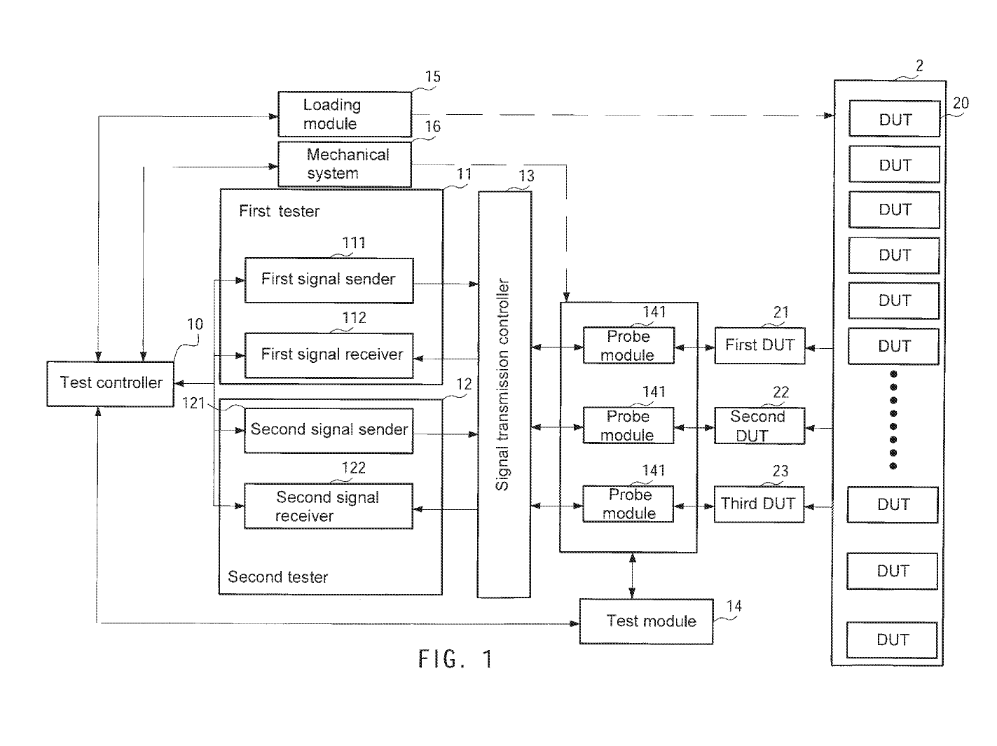

FIG. 1 is a block diagram of a system according to a first embodiment of the present invention. Referring to FIG. 1, the batch test system mainly performs a final test on a circuit module 2, for example, a wafer or a micro-strip before partitioning the circuit module 2, and performs a parallel test on a plurality of DUTs 20 on the circuit module 2 during the final test. In this embodiment, each DUT 20 has more than two capabilities of receiving/sending signals.

The batch test system includes a test controller 10, a loading module 15, a first tester 11, a second tester 12, a signal transmission controller 13, and a test module 14. The loading module 15 is used to load or unload the circuit module 2. Generally speaking, while loading the circuit module 2, the loading module 15 acquires configuration data. The configuration data records configuration positions of the DUTs 20 in the circuit module 2. The configuration data may be acquired as follows: the configuration data is obtained from a previous test machine table, for example, a machine table for performing a probing test; alternatively, the loading module 15 has a scanning capability to scan the circuit module 2 to establish the configuration data.

The test module 14 is externally connected to a plurality of probe modules 141 and is electrically coupled to at least two among all the DUTs 20 through the probe modules 141 according to the configuration positions of the DUTs 20 recorded in the configuration data. In this embodiment, the test module 14 is electrically coupled to a first DUT 21, a second DUT 22, and a third DUT 23 through three probe modules 141 at a time. However, the number of the coupled DUTs is not limited to three, and the test module 14 may also be electrically coupled to two, four, five, or other different number of DUTs 20 at a time. The test module 14 is mainly used to control the electrically coupled DUTs 20 to perform signal reception/sending and obtain operation conditions of the electrically coupled DUTs 20 through the probe modules 141.

The first tester 11 and the second tester 12 are used to perform a first signal test and a second signal test individually. The first tester 11 includes a first signal sender 111 and a first signal receiver 112. The first signal sender 111 is used to perform a first signal sending test. The first signal receiver 112 is used to perform a first signal receiving test. A combination of the first signal sending test and the first signal receiving test is deemed the complete content of the first signal test. Similarly, the second tester 12 includes a second signal sender 121 and a second signal receiver 122. The second signal sender 121 is used to perform a second signal sending test. The second signal receiver 122 is used to perform a second signal receiving test. A combination of the second signal sending test and the second signal receiving test is deemed the complete content of the second signal test.

However, the first tester 11 may perform the first signal sending test and the first signal receiving test in a sequence different from a sequence in which the second tester 12 performs the second signal sending test and the second signal receiving test, such that the first signal sending test and the second signal sending test are performed in parallel, and the first signal receiving test and the second signal receiving test are performed in parallel as well. Alternatively, the first signal sending test and the second signal receiving test are performed in parallel, and the first signal receiving test and the second signal sending test are performed in parallel.

In this embodiment, the first tester 11 and the second tester 12 are a Wireless Fidelity (WiFi) tester and a Bluetooth tester respectively. However, the first tester 11 and the second tester 12 may also be a WorldWide Interoperability for Microwave Access (Wimax) tester, a 3 G signal tester, a 3.5 G signal tester, and the like and are not limited to the above testers.

The signal transmission controller 13 is used to control signal transmission paths between the test module 14 and the first tester 11 and the second tester 12. Different path switching manners may be used for different parallel test manners and will be described later.

The test controller 10 is used to control the test module 14, the first tester 11, and the second tester 12 to individually perform the first signal test and second signal test on the first DUT 21, the second DUT 22, and the third DUT 23 electrically coupled to the test module 14 in parallel. Once the first signal test and the second signal test on any of all the DUTs 20 is completed, it is deemed that the test of the DUT is completed. Then, the test controller 10 acquires a test result of the tested DUT 20 from the test module 14 and records the test result in the configuration data contained in the loading module 15.

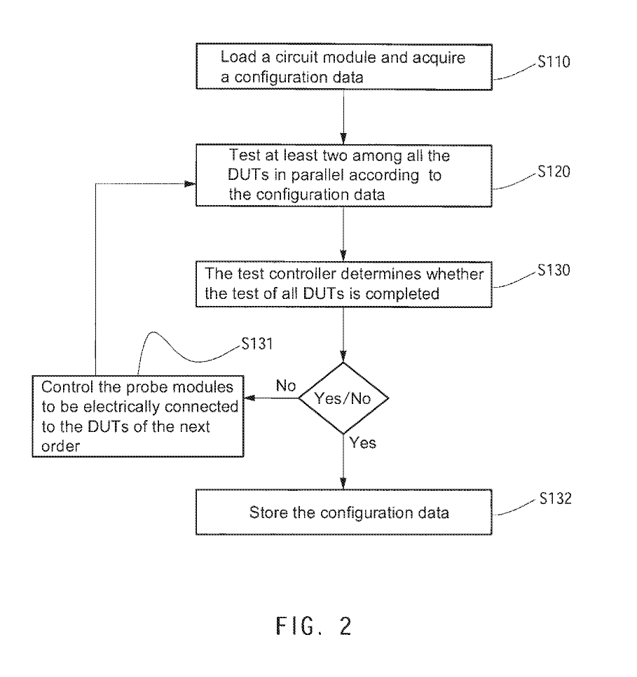

FIG. 2 is a flow chart of an SIP batch test method according to the first embodiment of the present invention. Referring to FIGS. 1 and 2, the method is applicable to a circuit module 2 having a plurality of DUTs 20. As described above, the circuit module 2 may be an unpartitioned wafer or a micro-strip. A plurality of DUTs 20 having working capabilities is configured on the circuit module 2, and it is set here that each DUT 20 has more than two capabilities of receiving/sending signals (but not limited thereto).

When wirings of the DUTs 20 are configured, the circuit module 2 performs a probing test. A test system for the probing test may be configured in the batch test system. As shown in FIG. 1, a mechanical system 16 is connected to the probe modules 141 and the test controller 10. When the loading module 15 scans the circuit module 2 and obtains configuration data, the test controller 10 commands the mechanical system 16 to perform the probing test. The mechanical system 16 controls the probe modules 141 to test each DUT 20 on the circuit module 2 to determine whether or not the wiring of the DUT 20 is normal. A test result of the probing test is returned to the test controller 10 through the test module 14. The test controller 10 records the test result of the probing test and determines whether or not any damaged DUT 20 exists according to the test result, thereby correcting the wiring of the damaged DUT 20 through a repair way, for example, a laser repair method. Afterwards, a molding operation is performed on the circuit module 2. The above is a standard practice for a general SIP and will not be described in detail herein. Afterwards, a final test for the circuit module 2 is performed, and herein the batch test system is utilized to perform a batch test process on the circuit module 2. The process includes the following steps.

A circuit module 2 is loaded and a configuration data that records configuration positions of a plurality of DUTs on the circuit module 2 is acquired (Step S110). As described previously, the loading module 15 scans the circuit module 2 to establish the configuration data while loading the circuit module 2. Alternatively, the loading module obtains the configuration data from other test equipment. However, in this embodiment, since the probing test is performed on the circuit module 2 by the batch test system, the configuration data should have been established.

At least two of all the DUTs are tested in parallel according to the configuration data (Step S120). As described previously, the test module 14 is electrically coupled to the first DUT 21, the second DUT 22, and the third DUT 23 through three probe modules 141, and the three probe modules 141 are electrically coupled to the first tester 11 and the second tester 12 through the signal transmission controller 13 such that the first DUT 21, the second DUT 22, and the third DUT 23 are electrically communicated with the first tester 11 and the second tester 12.

Parallel test has different test modes with respect to different internal architectures of the signal transmission controller.

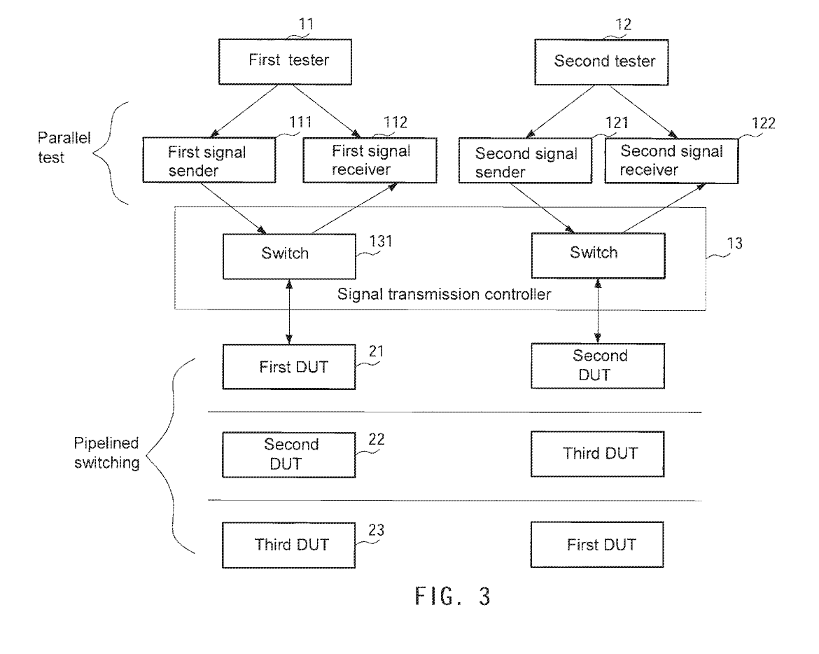

Firstly, FIG. 3 is a block diagram of an operation of a first type of parallel test in the present invention. The signal transmission controller 13 has two separate switches 131, and the first tester 11 and the second tester 12 are electrically coupled to two different DUTs 20 at the same time through the two switches 131. In this embodiment, the first tester 11 is a Bluetooth tester, the second tester 12 is an infrared tester, and each DUT 20 has the capabilities of receiving/sending Bluetooth signals and infrared signals. However, Bluetooth signals and infrared signals use the same frequency domain. Therefore, the DUTs 20 can only receive/send Bluetooth signals or infrared signals at a time, and thus each DUT 20 can only be connected to the single first tester 11 or second tester 12 at the same time so as to perform a Bluetooth signal test or an infrared signal test.

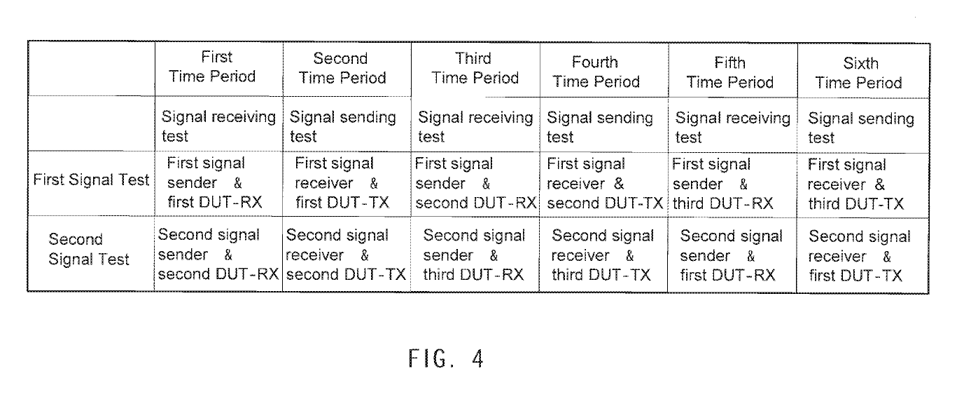

FIG. 4 is a timing diagram of the first type of parallel test in FIG. 3. Referring to FIGS. 3 and 4, in FIG. 3, the signal transmission controller 13 switches the DUTs 20 connected to the first tester 11 and the second tester 12 according to a pipelined rule. It is assumed herein that, the first tester 11 is connected to the first DUT 21, and the second tester 12 is connected to the second DUT 22.

In a first time period, the test controller 10 commands the first tester 11 to perform the first signal receiving test and commands the second tester 12 to perform the second signal receiving test. The first signal sender 111 sends a signal to a receiving port (Rx) of the first DUT 21, and the second signal sender 121 sends a signal to a receiving port (Rx) of the second DUT 22. The test module 14 obtains signal reception statuses of the first DUT 21 and the second DUT 22 through the probe modules 141 and returns the statuses to the test controller 10.

In a second time period, the test controller 10 commands the first tester 11 to perform the first signal sending test, commands the second tester 12 to perform the second signal sending test, and commands the first DUT 21 and the second DUT 22 to send signals through the test module 14. The first DUT 21 and the second DUT 22 send signals through respective transmit ports (Tx).

The first signal receiver 112 receives the signal sent by the first DUT 21, and the second signal receiver 122 receives the signal sent by the second DUT 22. The first signal receiver 112 and the second signal receiver 122 return their signal reception statuses to the test controller 10.

In a third time period, the two switches 131 switch the connected DUTs 20, such that the first tester 11 is connected to the second DUT 22, and the second tester 12 is connected to the third DUT 23. The test controller 10 commands the first signal sender 111 to perform the first signal receiving test on the second DUT 22, and commands the second signal sender 121 to perform the second signal receiving test on the third DUT 23. The test module 14 returns signal reception statuses of the first DUT 21 and the second DUT 22 to the test controller 10 through the probe modules 141.

In a fourth time period, the test controller 10 commands the first tester 11 to perform the first signal sending test, and commands the second tester 12 to perform the second signal sending test. The test controller 10 commands the second DUT 22 and the third DUT 23 to send signals through the test module 14 and commands the first signal receiver 112 to receive the signal sent by the second DUT 22 and the second signal receiver 122 to receive the signal sent by the third DUT 23. The first signal receiver 112 and the second signal receiver 122 return their signal reception statuses to the test controller 10.

At this time, the first signal test and the second signal test on the second DUT 22 are completed, and the test controller 10 stores a test result of the second DUT 22 in the configuration data.

In a fifth time period, the two switches switch the connected DUTs 20, such that the first tester 11 is connected to the third DUT 23, and the second tester 12 is connected to the first DUT 21. The test controller 10 commands the first signal sender 111 to perform the first signal receiving test on the third DUT 23, and commands the second signal sender 121 to perform the second signal receiving test on the first DUT 21. The test module 14 returns signal reception statuses of the third DUT 23 and the first DUT 21 to the test controller 10 through the probe modules 141.

In a sixth time period, the test controller 10 commands the third DUT 23 to perform the first signal sending test, and commands the first tester 11 to perform the second signal sending test. The test controller 10 commands the third DUT 23 and the first DUT 21 to send signals through the test module 14, and commands the first signal receiver 112 to receive the signal sent by the third DUT 23 and the second signal receiver 122 to receive the signal sent by the first DUT 21. The first signal receiver 112 and the second signal receiver 122 return their signal reception statuses to the test controller 10.

At this time, the first signal test and the second signal test on the first DUT 21 and the third DUT 23 are completed respectively, and the test controller 10 stores a test result of the second DUT 22 in the configuration data.

In this parallel test mode, the first signal sending test and the second signal sending test are performed in parallel, and the first signal receiving test and the second signal receiving test are performed in parallel. Two parallel execution statuses are in different time periods and are continuously executed sequentially. It should be noted that the so-called different time periods indicate that an execution time difference between two parallel execution statuses. That is, only one parallel execution status is in operation at a time, and the other parallel execution status is operated next time.

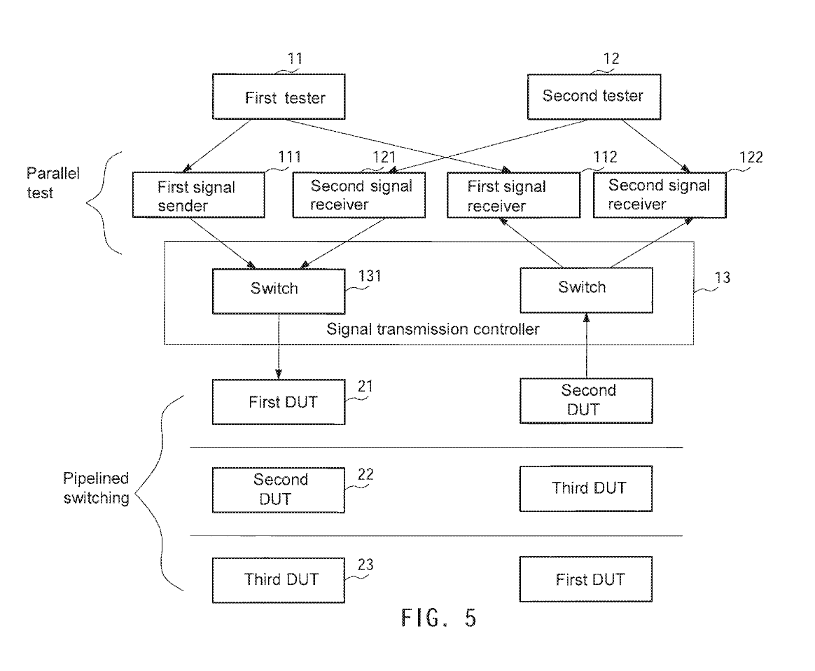

Secondly, FIG. 5 is a block diagram of an operation of a second type of parallel test in the present invention. Referring to FIG. 5, the signal transmission controller 13 has two separate switches 131. Two different DUTs 20 are connected to the first signal receiver 112 and the second signal receiver 122 at the same time or connected to the first signal sender 111 and the second signal sender 121 at the same time through the two switches 131. However, the switches 131 can only enable the DUTs 20 to communicate with the first signal sender 111 or the second signal sender 121, or enable the DUTs 20 to communicate with the first signal receiver 112 or the second signal receiver 122 at the same time.

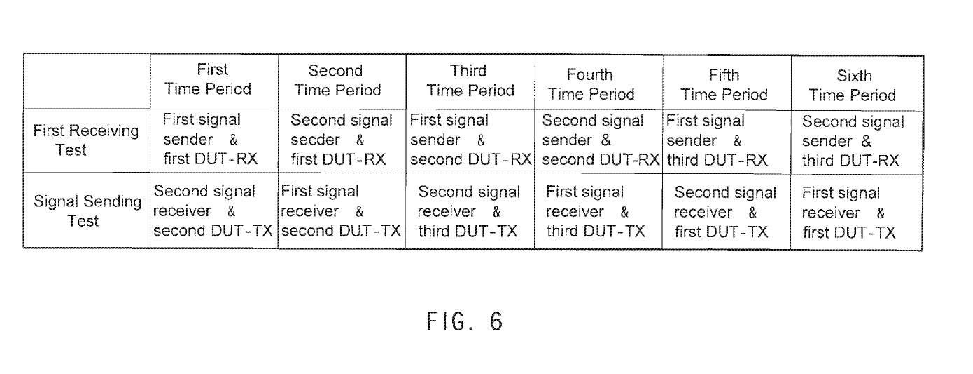

FIG. 6 is a timing diagram of the second type of parallel test in FIG. 5. Referring to FIGS. 5 and 6, the signal transmission controller 13 also switches the DUTs 20 connected to the first tester 11 and the second tester 12 according to a pipelined rule. It is assumed herein that the first DUT 21 is connected to the first signal sender 111 and the second signal sender 121, and the second DUT 22 is connected to the first signal receiver 112 and the second signal receiver 122 through the switch 131.

In a first time period, the test controller 10 commands the first tester 11 to perform the first signal receiving test and commands the second tester 12 to perform the second signal sending test. The first signal sender 111 sends a signal to a receiving port (Rx) of the first DUT 21. The test module 14 returns a signal reception status of the first DUT 21 to the test controller 10 through the probe module 141.

Meanwhile, the test controller 10 commands the second DUT 22 to send a signal through the test module 14. The second DUT 22 sends the signal via its transmit port (Tx). The second signal receiver 122 receives the signal sent by the second DUT 22. The second signal receiver 122 returns its signal reception status to the test controller 10.

In a second time period, the test controller 10 commands the second tester 12 to perform the second signal receiving test and commands the first tester 11 to perform the first signal sending test. The second signal sender 121 sends a signal to the receiving port (Rx) of the first DUT 21. The test module 14 obtains a signal reception status of the first DUT 21 through the probe module 141 and returns the status to the test controller 10.

Meanwhile, the test controller 10 commands the second DUT 22 to send a signal through the test module 14. The second DUT 22 sends the signal through its transmitting port (Tx). The first signal receiver 112 receives the signal sent by the second DUT 22. The first signal receiver 112 returns its signal reception status to the test controller 10.

In a third time period, the two switches 131 switch the connected DUTs 20, such that the second DUT 22 is connected to the first signal sender 111 and the second signal sender 121, and the third DUT 23 is connected to the first signal receiver 112 and the second signal receiver 122 through the switch 131.

The test controller 10 commands the second tester 12 to perform the first signal receiving test and commands the third DUT 23 to perform the second signal sending test. The first signal sender 111 sends a signal to a receiving port (Rx) of the second DUT 22. The test module 14 returns a signal reception status of the second DUT 22 to the test controller 10 through the probe module 141.

Meanwhile, the test controller 10 commands the third DUT 23 to send a signal through the test module 14. The third DUT 23 sends the signal through its transmitting port (Tx). The second signal receiver 122 receives the signal sent by the third DUT 23. The second signal receiver 122 returns its signal reception status to the test controller 10.

In a fourth time period, the test controller 10 commands the second tester 12 to perform the second signal receiving test and commands the first tester 11 to perform the first signal sending test. The second signal sender 121 sends a signal to the receiving port (Rx) of the second DUT 22. The test module 14 acquires a signal reception status of the second DUT 22 through the probe module 141 and returns the status to the test controller 10.

Meanwhile, the test controller 10 commands the second DUT 22 to send a signal through the test module 14. The third DUT 23 sends a signal through its transmitting port (Tx). The first signal receiver 112 receives the signal sent by the third DUT 23. The first signal receiver 112 returns its signal reception status to the test controller 10.

In a fifth time period, the two switches 131 switch the connected DUTs 20, such that the third DUT 23 is connected to the first signal sender 111 and the second signal sender 121, and the first DUT 21 is connected to the first signal receiver 112 and the second signal receiver 122 through the switch 131. The test controller 10 commands the first tester 11 to perform the first signal receiving test and commands the second tester 12 to perform the second signal sending test. The first signal sender 111 sends a signal to a receiving port (Rx) of the third DUT 23. The test module 14 returns a signal reception status of the third DUT 23 to the test controller 10 through the probe module 141.

Meanwhile, the test controller 10 commands the first DUT 21 to send a signal through the test module 14. The first DUT 21 sends a signal through its transmitting port (Tx). The second signal receiver 122 receives the signal sent by the first DUT 21. The first signal receiver 112 returns its signal reception status to the test controller 10.

In a sixth time period, the test controller 10 commands the second tester 12 to perform the second signal receiving test and commands the first tester 11 to perform the first signal sending test. The second signal sender 121 sends a signal to the receiving port (Rx) of the third DUT 23. The test module 14 acquires a signal reception status of the third DUT 23 through the probe module 141 and returns the status to the test controller 10.

Meanwhile, the test controller 10 commands the first DUT 21 to send a signal through the test module 14. The first DUT 21 sends the signal through its transmitting port (Tx). The first signal receiver 112 receives the signal sent by the first DUT 21. The first signal receiver 112 returns its signal reception status to the test controller 10.

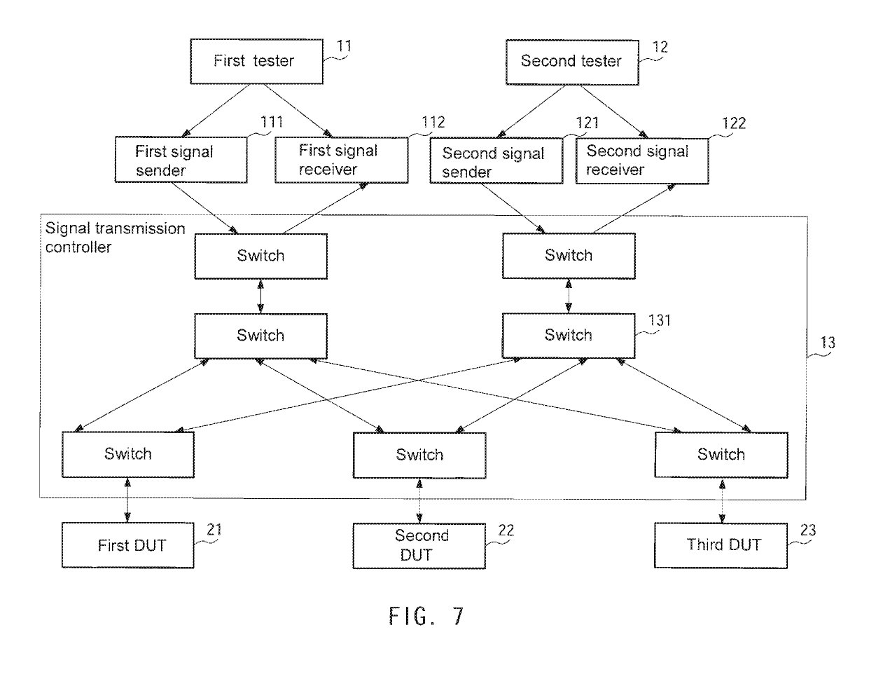

Firstly, FIG. 7 is a block diagram of an operation of a third type of parallel test in the present invention. Referring to FIG. 7, the signal transmission controller 13 has a plurality of levels of switches 131. Two switches 131 at the first level are used to switch signal transmission paths to the first tester 11 and the second tester 12. Two switches 131 at the second level are one-to-one connected switches 131 at the first level, and each switch 131 at the second level is connected to all switches 131 at the third level and used to switch signal transmission paths to the switches 131 at the third level. The three switches 131 at the third level are further connected to the first DUT 21, the second DUT 22, and the third DUT 23 respectively. Simultaneously, the first tester 11 and the second tester 12 are electrically coupled to two different DUTs 20 through the switches 131.

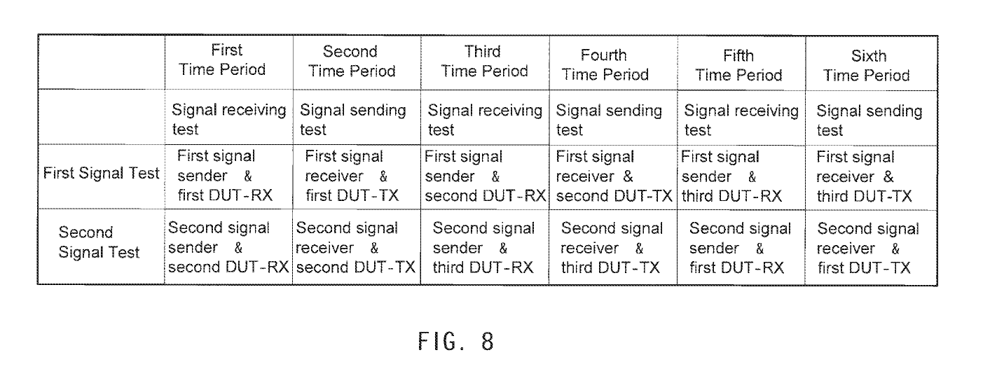

FIG. 8 is a timing diagram of the third type of parallel test in FIG. 7. Referring to FIGS. 7 and 8, in FIG. 8, the signal transmission controller 13 switches the DUTs 20 connected to the first tester 11 and the second tester 12 according to a switching rule. It is assumed herein that the first tester 11 is firstly connected to the first DUT 21, and the second tester 12 is connected to the second DUT 22 through the switches 131.

In a first time period, the test controller 10 commands the first tester 11 to perform the first signal receiving test and commands the second tester 12 to perform the second signal receiving test. The two switches 131 at the first level switch respective wirings to communicate with the first signal sender 111 and the second signal sender 121. The first signal sender 111 sends a signal to a receiving port (Rx) of the first DUT 21, and the second signal sender 121 sends a signal to a receiving port (Rx) of the second DUT 22. The test module 14 returns signal reception statuses of the first DUT 21 and the second DUT 22 to the test controller 10 through the probe modules 141.

In a second time period, the test controller 10 commands the first tester 11 to perform the first signal sending test, commands the second tester 12 to perform the second signal sending test, and commands the first DUT 21 and the second DUT 22 to send signals through the test module 14. The two switches 131 at the first level switch respective wirings to communicate with the first signal receiver 112 and the second signal receiver 122. The first DUT 21 and the second DUT 22 send signals through respective transmitting ports (Tx).

The first signal receiver 112 receives the signal sent by the first DUT 21, and the second signal receiver 122 receives the signal sent by the second DUT 22. The first signal receiver 112 and the second signal receiver 122 return their signal reception statuses to the test controller 10.

In a third time period, the switches 131 at the second level and the switches 131 at the third level switch the signal transmission paths, such that the first tester 11 is connected to the second DUT 22, and the second tester 12 is connected to the third DUT 23. The test controller 10 commands the first signal sender 111 to perform the first signal receiving test on the second DUT 22, and commands the second signal sender 121 to perform the second signal receiving test on the third DUT 23. The two switches 131 at the first level switch respective wirings to communicate with the first signal sender 111 and the second signal sender 121. The test module 14 returns signal reception statuses of the first DUT 21 and the second DUT 22 to the test controller 10 through the probe modules 141.

In a fourth time period, the test controller 10 commands the first tester 11 to perform the first signal sending test and commands the second tester 12 to perform the second signal sending test. The two switches 131 at the first level switch respective wirings to communicate with the first signal receiver 112 and the second signal receiver 122. The test controller 10 commands the second DUT 22 and the third DUT 23 to send signals through the test module 14 and commands the first signal receiver 112 to receive the signal sent by the second DUT 22 and the second signal receiver 122 to receive the signal sent by the third DUT 23. The first signal receiver 112 and the second signal receiver 122 return their signal reception statuses to the test controller 10.

At this time, the first signal test and the second signal test on the second DUT 22 are completed, and the test controller 10 stores a test result of the second DUT 22 in the configuration data.

In a fifth time period, the switches 131 at the second level and the switches 131 at the third level switch the signal transmission paths, such that the first tester 11 is connected to the third DUT 23, and the second tester 12 is connected to the first DUT 21. The two switches 131 at the first level switch respective wirings to communicate with the first signal sender 111 and the second signal sender 121. The test controller 10 commands the first signal sender 111 to perform the first signal receiving test on the third DUT 23 and commands the second signal sender 121 to perform the second signal receiving test on the first DUT 21. The test module 14 returns signal reception statuses of the third DUT 23 and the first DUT 21 to the test controller 10 through the probe modules 141.

In a sixth time period, the test controller 10 commands the third tester 17 to perform the first signal sending test and commands the first tester 11 to perform the second signal sending test. The two switches 131 at the first level switch respective wirings to communicate with the first signal receiver 112 and the second signal receiver 122. The test controller 10 commands the third DUT 23 and the first DUT 21 to send signals through the test module 14 and commands the first signal receiver 112 to receive the signal sent by the third DUT 23 and the second signal receiver 122 to receive the signal sent by the first DUT 21. The first signal receiver 112 and the second signal receiver 122 return their signal reception statuses to the test controller 10.

So far, the first signal test and the second signal test on the first DUT 21, the second DUT 22, and the third DUT 23 have been completed.

However, no matter what kind of above test modes or test structures are proceed, when any failure device is detected (any DUT 20 does not pass the test), the configuration position of the failure device in the configuration data will be marked by the test controller 10.

The test controller 10 determines whether or not the test of all DUTs 20 is completed (Step S130). When it is determined that the test is not completed, the test controller 10 commands the test module 14 to control the probe modules 141 to electrically connect the DUTs 20 of the next order based on the configuration positions and sequences of the DUTs 20 recorded in the configuration data (Step S131), thereby performing Step S120 again. Otherwise, the configuration data is saved appropriately (Step S132). After performing a subsequent partitioning operation on the circuit module 2, the manufacturer may classify the partitioned DUTs 20 according to the test records recorded in the configuration data for quality control.

As known from the above, the first signal test and the second signal test need to be performed on each of the three DUTs. The two signal tests respectively have two detail tests, each detail test needs a time period, and each DUT needs four time periods. Therefore, the completion of the test on the three DUTs needs 12 time periods. However, in the above batch test system and batch test method, the completion of the test on the three DUTs needs only six time periods so that the total test time of all DUTs is exactly shortened.

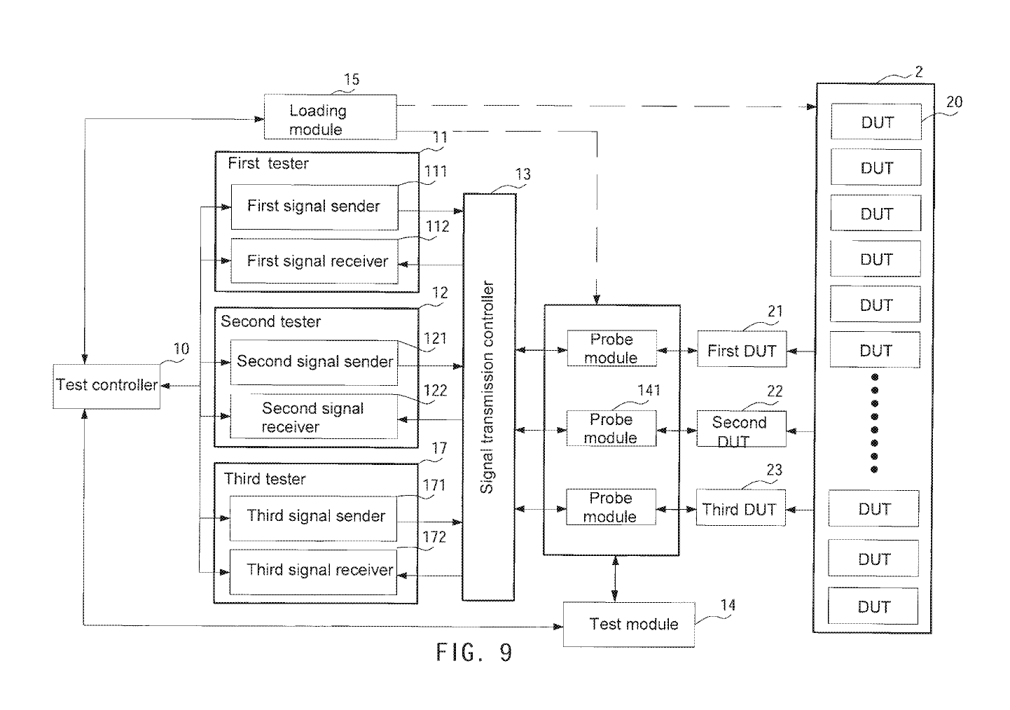

FIG. 9 is a block diagram of a system according to a second embodiment of the present invention. Referring to FIG. 9, the difference between the second embodiment and the first embodiment lies is in that the system of the second embodiment further includes a third tester 17. The third tester 17 is used to perform a third test. The third tester 17 includes a third signal sender 171 and a third signal receiver 172. The third signal sender 171 is used to perform a third signal sending test, and the third signal receiver 172 is used to perform a third signal receiving test. A combination of the third signal sending test and the third signal receiving test is deemed the complete content of the third signal test.

However, the sequences in which the first tester 11 performs the first signal test, the second tester 12 performs the second signal test, and the third tester 17 performs the third signal test are substantially synchronous, such that the first signal sending test, the second signal sending test, and the third signal sending test are performed in parallel, and the first signal receiving test, the second signal receiving test, and the third signal receiving test are performed in parallel as well.

The SIP batch test method used by the second system architecture has the same process as shown in FIG. 2, and only signal transmission structures of the first tester 11, the second tester 12, and the third tester 17 for the three DUTs in Step S120 are described herein. Similarly, Parallel test has different test modes with respect to different internal architectures of the signal transmission controller 13.

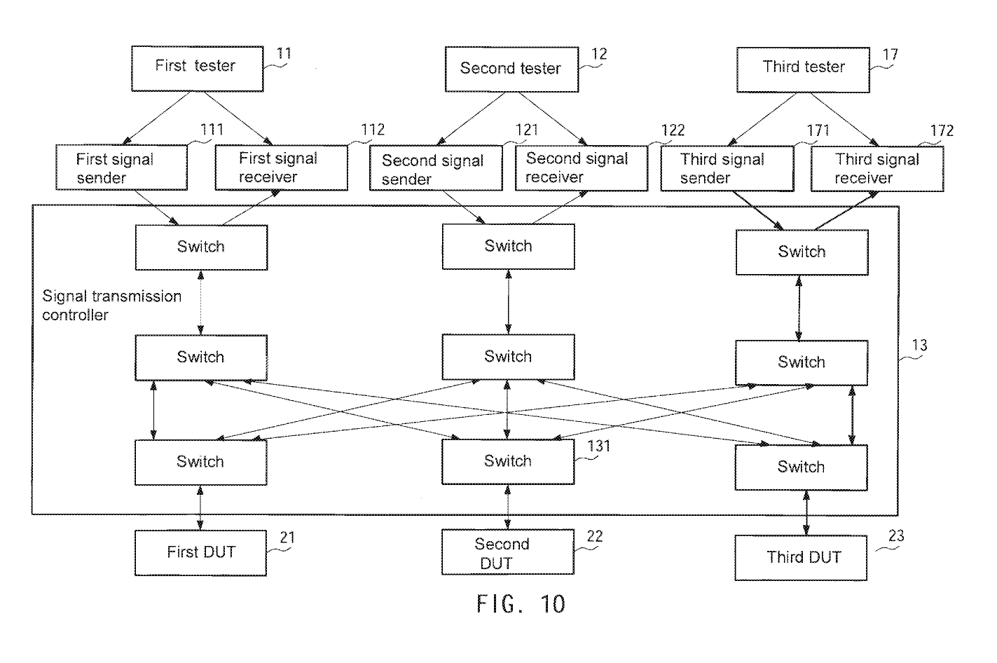

Firstly, FIG. 10 is a block diagram of an operation of a fourth type of parallel test in the present invention. The signal transmission controller 13 has a plurality of levels of switches 131. Three switches 131 at the first level are used to switch signal transmission paths to the first tester 11, the second tester 12, and the third tester 17. Three switches 131 at the second level are one-to-one connected switches 131 at the first level, and each switch 131 at the second level is connected to all switches 131 at the third level and used to switch signal transmission paths to the switches 131 at the third level. The three switches 131 at the third level are further respectively connected to the first DUT 21, the second DUT 22, and the third DUT 23. The first tester 11, the second tester 12, and the third tester 17 are electrically coupled to the three different DUTs through the switches 131 at these levels at the same time.

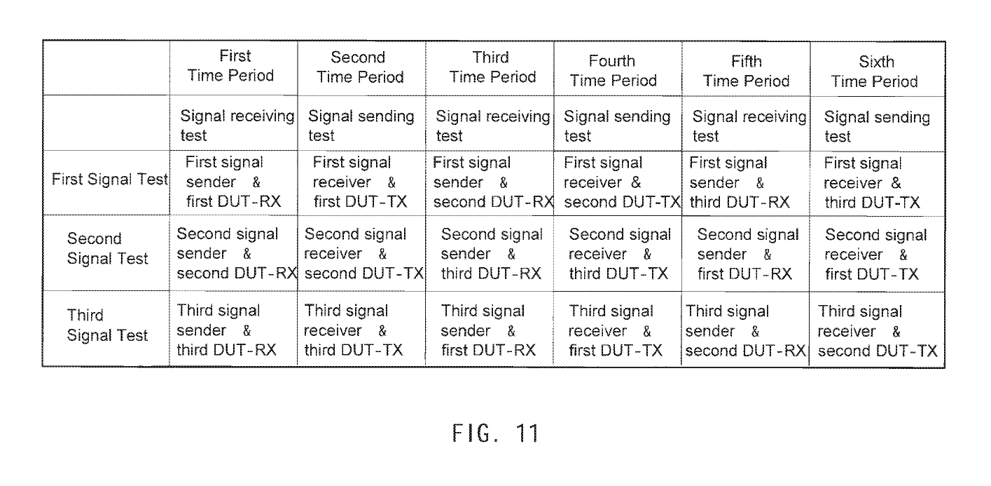

FIG. 11 is a timing diagram of the fourth type of parallel test in FIG. 10. Referring to FIGS. 10 and 11, in FIG. 11, the signal transmission controller 13 switches the DUTs connected to the first tester 11, the second tester 12, and the third tester 17 according to a switching rule. It is assumed herein that the first tester 11 is firstly connected to the first DUT 21, the second tester 12 is connected to the second DUT 22, and the third tester 17 is connected to the third DUT 23 through the switches 131.

In a first time period, the test controller 10 commands the first tester 11 to perform the first signal receiving test, commands the second tester 12 to perform the second signal receiving test, and commands the third tester 17 to perform the third signal receiving test. The three switches 131 at the first level switch respective wirings to communicate with the first signal sender 111, the second signal sender 121, and the third signal sender 171. The first signal sender 111 sends a signal to a receiving port (Rx) of the first DUT 21, the second signal sender 121 sends a signal to a receiving port (Rx) of the second DUT 22, and the third signal sender 171 sends a signal to a receiving port (Rx) of the third DUT 23. The test module 14 returns signal reception statuses of the first DUT 21, the second DUT 22, and the third DUT 23 to the test controller 10 through the probe modules 141.

In a second time period, the test controller 10 commands the first tester 11 to perform the first signal sending test, commands the second tester 12 to perform the second signal sending test, commands the third tester 17 to perform the third signal sending test, and commands the first DUT 21, the second DUT 22, and the third DUT 23 to respectively send signals through the test module 14. The three switches 131 at the first level switch respective wirings to communicate with the first signal receiver 112, the second signal receiver 122, and the third signal receiver 172. The first DUT 21, the second DUT 22, and the third DUT 23 send signals through respective transmitting ports (Tx).

The first signal receiver 112 receives the signal sent by the first DUT 21, the second signal receiver 122 receives the signal sent by the second DUT 22, and the third signal receiver 172 receives the signal sent by the third DUT 23. The first signal receiver 112, the second signal receiver 122, and the third signal receiver 172 return their signal reception statuses to the test controller 10.

In a third time period, the switches 131 at the second level and the switches 131 at the third level switch signal transmission paths, such that the first tester 11 is connected to the second DUT 22, the second tester 12 is connected to the third DUT 23, and the third tester 17 is connected to the first DUT 21. The test controller 10 commands the first signal sender 111 to perform the first signal receiving test on the second DUT 22, commands the second signal sender 121 to perform the second signal receiving test on the third DUT 23, and commands the third signal sender 171 to perform the second signal receiving test on the first DUT 21. The three switches 131 at the first level switch respective wirings to communicate with the first signal sender 111, the second signal sender 121, and the third signal sender 171. The test module 14 returns signal reception statuses of the first DUT 21, the second DUT 22, and the third DUT 23 to the test controller 10 through the probe modules 141.

In a fourth time period, the test controller 10 commands the first tester 11 to perform the first signal sending test, commands the second tester 12 to perform the second signal sending test, and commands the third tester 17 to perform the third signal sending test. The three switches 131 at the first level switch respective wirings to communicate with the first signal receiver 112, the second signal receiver 122, and the third signal receiver 172. The test controller 10 commands the first DUT 21, the second DUT 22, and the third DUT 23 to send signals through the test module 14, and commands the first signal receiver 112 to receive the signal sent by the second DUT 22, the second signal receiver 122 to receive the signal sent by the third DUT 23, and the third signal receiver 172 to receive the signal sent by the first DUT 21. The first signal receiver 112, the second signal receiver 122, and the third signal receiver 172 return their signal reception statuses to the test controller 10.

In a fifth time period, the switches 131 at the second level and the switches 131 at the third level switch signal transmission paths, such that the first tester 11 is connected to the third DUT 23, the second tester 12 is connected to the first DUT 21, and the third tester 17 is connected to the second DUT 22. The three switches 131 at the first level switch respective wirings to communicate with the first signal sender 111, the second signal sender 121, and the third signal sender 171. The test controller 10 commands the first signal sender 111 to perform the first signal receiving test on the third DUT 23, commands the second signal sender 121 to perform the second signal receiving test on the first DUT 21, and commands the third signal sender 171 to perform the third signal receiving test on the second DUT 22. The test module 14 returns signal reception statuses of the third DUT 23 and the first DUT 21 to the test controller 10 through the probe modules 141.

In a sixth time period, the test controller 10 commands the third tester 17 to perform the first signal sending test, commands the first tester 11 to perform the second signal sending test, and commands the second tester 12 to perform the third signal sending test. The three switches 131 at the first level switch respective wirings to communicate with the first signal receiver 112, the second signal receiver 122, and the third signal receiver 172. The test controller 10 commands the third DUT 23, the second DUT 22, and the first DUT 21 to send signals through the test module 14 and commands the first signal receiver 112 to receive the signal sent by the third DUT 23, the second signal receiver 122 to receive the signal sent by the first DUT 21, and the third signal receiver 172 to receive the signal sent by the second DUT 22. The first signal receiver 112, the second signal receiver 122, and the third signal receiver 172 return their signal reception statuses to the test controller 10.

So far, the first signal test, the second signal test, and the third signal test on the first DUT 21, the second DUT 22, and the third DUT 23 are completed.

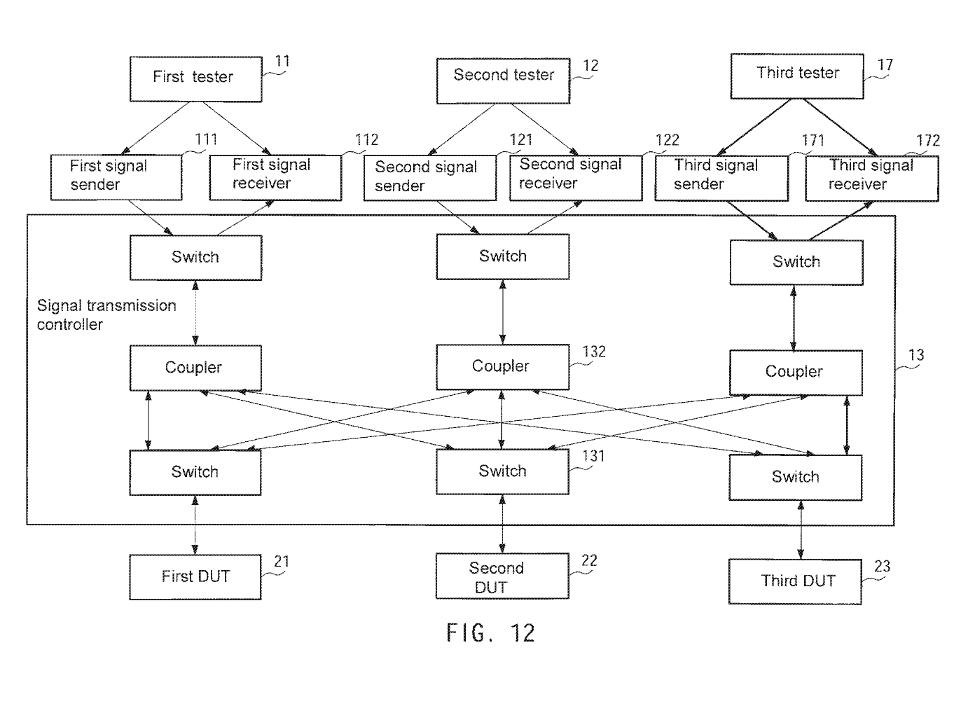

Secondly, FIG. 12 is a block diagram of an operation of a fifth type of parallel test in the present invention. The signal transmission controller 13 includes a plurality of switches 131 and couplers 132. Three switches 131 at the first level are used to switch signal transmission paths to the first tester 11, the second tester 12, and the third tester 17. Three couplers 132 at the second level are one-to-one connected switches 131 at the first level, and each coupler 132 at the second level is electrically coupled and connected to all switches 131 at the third level, thereby differentiating signal transmission paths to the switches 131 at the third level according to the difference and attenuation of signal strength on various signal ports. The three switches 131 at the third level are further respectively connected to the first DUT 21, the second DUT 22, and the third DUT 23. The first tester 11, the second tester 12, and the third tester 17 are electrically coupled to the three different DUTs through the switches 131 and the couplers 132 at these levels at the same time.

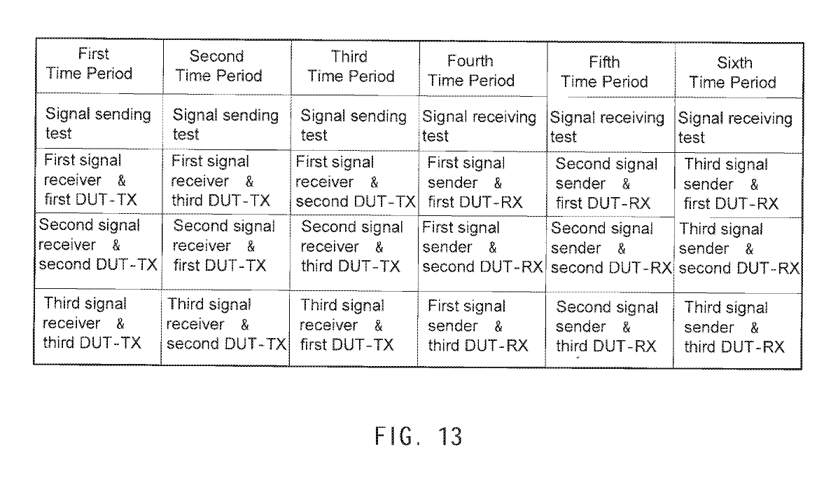

FIG. 13 is a timing diagram of the fifth type of parallel test in FIG. 12. Referring to FIGS. 12 and 13, in FIG. 12, the signal transmission controller 13 switches the DUTs connected to the first tester 11, the second tester 12, and the third tester 17 according to a switching rule. It is assumed herein that the first tester 11 is firstly connected to the first DUT 21, the second tester 12 is connected to the second DUT 22, and the third tester 17 is connected to the third DUT 23 through the switches 131 and the couplers 132.

In a first time period, the test controller 10 commands the first tester 11 to perform the first signal sending test, commands the second tester 12 to perform the second signal sending test, commands the third tester 17 to perform the third signal sending test, and commands the first DUT 21, the second DUT 22, and the third DUT 23 to respectively send signals through the test module 14. The three switches 131 at the first level switch respective wirings to communicate with the first signal receiver 112, the second signal receiver 122, and the third signal receiver 172. The first DUT 21, the second DUT 22, and the third DUT 23 send signals via respective transmitting ports (Tx).

The first signal receiver 112 receives the signal sent by the first DUT 21, the second signal receiver 122 receives the signal sent by the second DUT 22, and the third signal receiver 172 receives the signal sent by the third DUT 23. The first signal receiver 112, the second signal receiver 122, and the third signal receiver 172 return their own signal reception statuses to the test controller 10.

In a second time period, the couplers 132 at the second level and the switches 131 at the third level switch signal transmission paths, such that the first tester 11 is connected to the third DUT 23, the second tester 12 is connected to the first DUT 21, and the third tester 17 is connected to the second DUT 22. The test controller 10 similarly commands the first tester 11 to perform the first signal sending test, commands the second tester 12 to perform the second signal sending test, commands the third tester 17 to perform the third signal sending test, and commands the first DUT 21, the second DUT 22, and the third DUT 23 to respectively send signals through the test module 14. The three switches 131 at the first level switch respective wirings to communicate with the first signal receiver 112, the second signal receiver 122, and the third signal receiver 172. The first DUT 21, the second DUT 22, and the third DUT 23 send signals through respective transmitting ports (Tx).

The first signal receiver 112 receives the signal sent by the third DUT 23, the second signal receiver 122 receives the signal sent by the first DUT 21, and the third signal receiver 172 receives the signal sent by the second DUT 22. The first signal receiver 112, the second signal receiver 122, and the third signal receiver 172 return their signal reception statuses to the test controller 10.

In a third time period, the couplers 132 at the second level and the switches 131 at the third level switch signal transmission paths, such that the first tester 11 is connected to the second DUT 22, the second tester 12 is connected to the third DUT 23, and the third tester 17 is connected to the first DUT 21. The test controller 10 similarly commands the first tester 11 to perform the first signal sending test, commands the second tester 12 to perform the second signal sending test, commands the third tester 17 to perform the third signal sending test, and commands the first DUT 21, the second DUT 22, and the third DUT 23 to respectively send signals through the test module 14. The three switches 131 at the first level switch respective wirings to communicate with the first signal receiver 112, the second signal receiver 122, and the third signal receiver 172. The first DUT 21, the second DUT 22, and the third DUT 23 send signals through respective transmitting ports (Tx).

The first signal receiver 112 receives the signal sent by the second DUT 22, the second signal receiver 122 receives the signal sent by the third DUT 23, and the third signal receiver 172 receives the signal sent by the first DUT 21. The first signal receiver 112, the second signal receiver 122, and the third signal receiver 172 return their signal reception statuses to the test controller 10.

In a fourth time period, the couplers 132 at the second level and the switches 131 at the third level switch signal transmission paths, such that the first tester 11 communicates with the first DUT 21, the second DUT 22, and the third DUT 23 at same time. The test controller 10 commands the first signal sender 111 to perform the first signal receiving test on the first DUT 21, the second DUT 22, and the third DUT 23. The test module 14 returns signal reception statuses of the third DUT 23, the second DUT 22, and the first DUT 21 to the test controller 10 through the probe modules 141.

In a fifth time period, the couplers 132 at the second level and the switches 131 at the third level switch signal transmission paths, such that the second tester 12 communicates with the first DUT 21, the second DUT 22, and the third DUT 23 at same time. The test controller 10 commands the second signal sender 121 to perform the second signal receiving test on the first DUT 21, the second DUT 22, and the third DUT 23. The test module 14 returns signal reception statuses of the third DUT 23, the second DUT 22, and the first DUT 21 to the test controller 10 through the probe modules 141.

In a sixth time period, the couplers 132 at the second level and the switches 131 at the third level switch signal transmission paths, such that the third tester 17 communicates with the first DUT 21, the second DUT 22, and the third DUT 23 one time. The test controller 10 commands the third signal sender 171 to perform the second signal receiving test on the first DUT 21, the second DUT 22, and the third DUT 23. The test module 14 returns signal reception statuses of the third DUT 23, the second DUT 22, and the first DUT 21 to the test controller 10 through the probe modules 141.

So far, the first signal test, the second signal test, and the third signal test on the first DUT 21, the second DUT 22, and the third DUT 23 have been completed.

As known from the above, the first signal test, the second signal test, and the third signal test need to be performed on each of the three DUTs. The three signal tests respectively have two detail tests, each detail test needs a time period, and each DUT needs six time periods. Therefore, the completion of the test on the three DUTs needs 18 time periods. However, in the above batch test system and batch test method, the completion of the test on the three DUTs needs only six time periods, so the total test time of all DUTs is shortened.

Although the present invention has been disclosed above by the aforementioned preferred embodiments, the disclosure does not intend to limit the present invention. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A system in package (SIP) batch test system, applicable to testing an unpartitioned circuit module comprising a plurality of devices under test (DUTs), the batch test system comprising:
a loading module, for loading the circuit module and acquiring configuration data, wherein the configuration data records configuration positions of the DUTs on the circuit module;
a test module, for electrically coupling at least two DUTs among the DUTs and controlling the at least two DUTs to receive/send signals;
a first tester, for performing a first signal test;
a second tester, for performing a second signal test;
a signal transmission controller, for controlling signal transmission paths between the test module and the first tester and the second tester; and
a test controller, for controlling the test module, the first tester, and the second tester to perform the first signal test and the second signal test on the at least two different DUTs in parallel, and record a test result of any one of the DUTs in the configuration data contained in the loading module when the first signal test and the second signal test on the DUT are completed.

2. The batch test system according to claim 1, wherein the circuit module is a wafer.

3. The batch test system according to claim 1, wherein the circuit module is an unpartitioned micro-strip.

4. The batch test system according to claim 1, wherein the first tester is a Wireless Fidelity (WiFi) tester, and the second tester is a Bluetooth tester.

5. The batch test system according to claim 1, wherein the first signal test comprises a first signal sending test and a first signal receiving test, the second signal test comprises a second signal sending test and a second signal receiving test, the first tester sequentially performs the first signal sending test and the first signal receiving test, and the second tester sequentially performs the second signal sending test and the second signal receiving test.

6. The batch test system according to claim 5, wherein the first signal receiving test and the second signal receiving test are performed in parallel, and the first signal sending test and the second signal sending test are performed in parallel.

7. The batch test system according to claim 5, wherein the first signal receiving test and the second signal sending test are performed in parallel, and the first signal sending test and the second signal receiving test are performed in parallel.

8. The batch test system according to claim 1, further comprising a third tester connected to the test controller and the signal transmission controller, wherein the third tester is used to perform a third signal test through a signal transmission path between the signal transmission controller and the loading module, and the test controller controls the test module, the first tester, the second tester, and the third tester, so as to individually perform the first signal test, the second signal test, and the third signal test on the at least three DUTs in parallel.

9. The batch test system according to claim 8, wherein the first signal test comprises a first signal sending test and a first signal receiving test, the second signal test comprises a second signal sending test and a second signal receiving test, the third signal test comprises a third signal sending test and a third signal receiving test, the first tester sequentially performs the first signal sending test and the first signal receiving test, the second tester sequentially performs the second signal sending test and the second signal receiving test, and the third tester sequentially performs the third signal sending test and the third signal receiving test.

10. The batch test system according to claim 9, wherein the first signal receiving test, the second signal receiving test, and the third signal receiving test are performed in parallel, and the first signal sending test, the second signal sending test, and the third signal sending test are performed in parallel.

11. A system in package (SIP) batch test method, comprising:
loading a circuit module and acquiring configuration data, wherein the configuration data records configuration positions of a plurality of devices under test (DUTs) on the circuit module;
testing at least two DUTs among the DUTs in parallel according to the configuration data;
recording a plurality of test results of the at least two DUTs in the configuration data; and
determining whether or not the test on all the DUTs is completed, and if not, returning to the step of testing at least two DUTs among the DUTs in parallel according to the configuration data.

12. The SIP batch test method according to claim 11, wherein the step of testing at least two DUTs among the DUTs in parallel according to the configuration data comprises individually performing a first signal test and a second signal test on the at least two DUTs in parallel.

13. The SIP batch test method according to claim 12, wherein the first signal test comprises a first signal sending test and a first signal receiving test, the second signal test comprises a second signal sending test and a second signal receiving test, the first signal receiving test and the second signal receiving test are performed in parallel, and the first signal sending test and the second signal sending test are performed in parallel.

14. The SIP batch test method according to claim 12, wherein the first signal test comprises a first signal sending test and a first signal receiving test, the second signal test comprises a second signal sending test and a second signal receiving test, the first signal receiving test and the second signal sending test are performed in parallel, and the first signal sending test and the second signal receiving test are performed in parallel.

15. The SIP batch test method according to claim 11, wherein the step of testing at least two DUTs among the DUTs in parallel according to the configuration data comprises individually performing a first signal test, a second signal test, and a third signal test on at least three DUTs in parallel.

16. The SIP batch test method according to claim 15, wherein the first signal test comprises a first signal sending test and a first signal receiving test, the second signal test comprises a second signal sending test and a second signal receiving test, the third signal test comprises a third signal sending test and a third signal receiving test, the first signal receiving test, the second signal receiving test, and the third signal receiving test are performed in parallel, and the first signal sending test, the second signal sending test, and the third signal sending test are performed in parallel.

17. The SIP batch test method according to claim 11, wherein the step of recording a plurality of test results of the DUTs in the configuration data comprises marking a configuration position of any failure device in the configuration data when the failure device exists.
